(19) United States
(12) Patent Application Publication
(10) Pub. No.: US 2026/0157148 A1
(43) Pub. Date: Jun. 4, 2026

(54) TEMPERATURE TUNING BY EMISSIVITY VARIATION ON SUSCEPTOR BY LASER PATTERNING

(71) Applicant: Applied Materials, Inc., Santa Clara, CA (US)

(72) Inventors: Kim Ramkumar VELLORE, San Jose, CA (US); Paul BRILLHART, Pleasanton, CA (US); Marc SHULL, San Jose, CA (US)

(21) Appl. No.: 18/968,996

(22) Filed: Dec. 4, 2024

(51) Int. Cl. H01L 21/687; H01L 21/67

(52) U.S. Cl. CPC H10P 72/7616; H10P 72/0436

(57) ABSTRACT

An apparatus, a method, and system for temperature tuning by emissivity variation on susceptor by laser patterning. In an embodiment, a method for performing laser patterning on a chamber component of a processing chamber is provided. The method includes receiving a chamber component of a processing chamber and performing laser patterning on one side of the chamber component of the processing chamber to form a plurality of patterned regions and a non-patterned region. The plurality of patterned regions having a different emissivity than the non-patterned region.

### BACKGROUND

### Field

The present disclosure relates to semiconductor manufacturing and processing. More particularly, the disclosure relates to an apparatus, method, and system for fabricating devices on a semiconductor substrate. Specifically, embodiments of the present disclosure provide an apparatus, method, and system for temperature tuning by emissivity variation on susceptor by laser patterning.

### Description of the Related Art

Semiconductor substrates are processed for a wide range of applications, including the fabrication of integrated devices and microdevices. One method of processing substrates includes depositing a material, such as a semiconductor material or a conductive material, on an upper surface of the substrate. For example, epitaxy is a deposition process that deposit films of various materials on the surface of a substrate in a processing chamber. Since temperature is one factor affecting deposition of these films, adequate thermal management of the substrate temperature is beneficial to control the growth of the deposited film. During processing, various thermal parameters determined by the chamber (e.g. lift pins and regions under the arms) can affect the uniformity of material deposited on the substrate.

Therefore, a need exists for improved apparatuses, methods and systems for processing substrates.

### SUMMARY

The present disclosure provides an apparatus, method, and system for temperature tuning by emissivity variation on susceptor by laser patterning.

In one or more embodiments, a chamber component of a processing chamber is provided. The chamber component of the processing chamber includes a body and plurality patterned regions and a non-patterned region. The plurality of patterned regions having a different emissivity than the non-patterned region.

In one or more embodiments, a method of laser patterning on a chamber component of a processing chamber is provided. The method includes positioning a chamber component of a processing chamber and performing laser patterning on one side of the chamber component of the processing chamber to form a plurality of patterned regions and a non-patterned region. The plurality of patterned regions having a different emissivity than the non-patterned region.

In one or more embodiments, a processing system configured to perform a process on a substrate is provided. The processing system includes a chamber body, a plurality of lamps, and a silicon carbide coated susceptor disposed inside the chamber body. The silicon carbide coated susceptor having a plurality of patterned regions and a non-patterned region, and the plurality of patterned regions having a different emissivity than the non-patterned regions.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic diagram showing a cross-sectional view of a process chamber, according to embodiments of the present disclosure.

FIG. 2A shows a plan view of an example substrate support or susceptor in the process chamber of FIG. 1, according to embodiments of the present disclosure.

FIG. 2B shows a plan view of the back of the substrate support or susceptor of FIG. 1, according to embodiments of the present disclosure.

FIG. 3A shows a plan view of the back side of the substrate support or susceptor where a plurality of patterned regions and a non-patterned region are shown to have different emissivity values, according to embodiments of the present disclosure.

FIG. 3B shows a schematic plot of the temperature as a function of emissivity values, according to embodiments of the present disclosure.

FIG. 4 shows a laser patterning system, according to embodiments of the present disclosure.

FIG. 5 shows a schematic flow diagram view of the method 500 of laser patterning on the substrate support or susceptor of FIG. 1, according to embodiments of the present disclosure.

FIGS. 6A and 6B illustrate examples of non-uniform thickness maps, in accordance with the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor manufacturing and processing. More particularly, the disclosure relates to an apparatus, method, and system for fabricating devices on a semiconductor substrate. Specifically, embodiments of the present disclosure provide an apparatus, method, and system for temperature tuning by emissivity variation on susceptor by laser patterning.

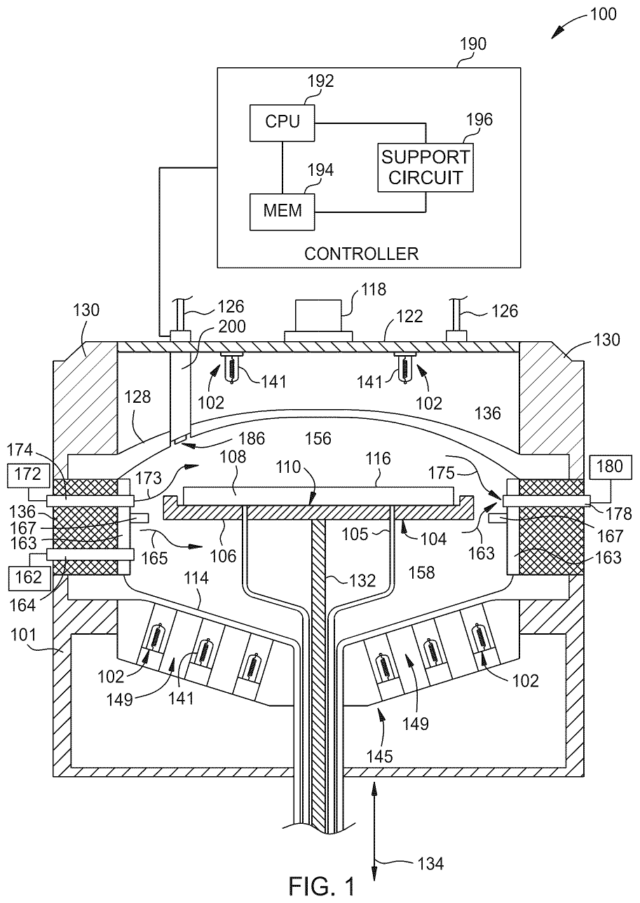

FIG. 1 shows a schematic sectional view of a processing chamber 100 having substrate support 106, such as a susceptor, and a plurality of heating lamps 102, according to embodiments of the present disclosure. The process chamber 100 may be configured to perform epitaxial deposition processes. The process chamber 100 may be used to process one or more substrates, including the deposition of a material on an upper surface of a substrate 108.

The processing chamber 100 includes an upper body 130 and a lower body 101 and a flow module 136 disposed between the upper body 130 and the lower body 101. The upper body 130, the flow module 136, and the lower body 101 form a chamber body. Disposed within the chamber body and defining an internal region of the process chamber 100 are the substrate support 106, an upper plate 128 (such as an upper window and/or an upper dome), a lower plate 114 (such a lower window and/or a lower dome), and one or more upper heat and lower heat sources 141. The present disclosure contemplates that each of the heat sources described herein can include one or more of: lamp(s), resistive heaters(s), light emitting diodes(s) (LEDs), and/or laser(s). The present disclosure further contemplates that other heat sources can be used. The present disclosure contemplates that the upper plate 128 and/or the lower plate 114 can be in the shape of a dome or can be in another shape, such as flat, concave, or other contour. In one or more embodiments, the central window portion of the upper plate 128 and the bottom of the lower plate 114 are formed from an optically transparent material, such as quartz.

A reflector 122 may be optionally placed outside the upper plate 128 to reflect infrared light that is radiating off the substrate 108 back onto the substrate 108. The reflector 122 may be secured to the upper plate 128 using a clamp ring (not shown) attached to the upper body 130. The reflector 122 can be made of a metal such as aluminum or stainless steel. The efficiency of the reflection can be improved by coating a reflector area with a highly reflective coating such as with gold. The reflector 122 can have one or more conduits 126 connected to a cooling source (not shown). The conduit 126 connects to a passage (not shown) formed on a side of, or within, the reflector 122. The passage is configured to carry a flow of a fluid such as water and may run horizontally along the side of the reflector 122 in any desired pattern covering a portion or entire surface of the reflector 122 for cooling the reflector 122.

The process chamber 100 may include an array of radiant heating lamps 102, for heating, disposed within the process chamber 100 below and/or above the substrate support 106 for heating the substrate support 106 or the substrate support 108 disposed therein. The lamps 102 may be configured to include bulbs 141 and be configured to heat the substrate 108 to a temperature within a range of about 200 degrees Celsius to about 1600 degrees Celsius. Each lamp 102 is coupled to a power distribution board (not shown) through which power is supplied to each lamp 102. The lamps 102 may be positioned within a lamphead 145 which may be cooled during or after processing by, for example, a cooling fluid introduced into channels 149 located between the lamps 102. The lamphead 145 conductively and radiatively cools the lower plate 114 due in part to the close proximity of the lamphead 145 to the lower plate 114. The lamphead 145 may also cool the lamp walls and walls of the reflectors (not shown) around the lamps 102. Alternatively, the lower plate 114 may be cooled by convection. Depending upon the application, the lamphead 145 may or may not be in contact with the lower plate 114.

In one or more embodiments the array of radiant heating lamps 102 is disposed over the upper plate 128 as well as adjacent to and beneath the lower plate 114 in a specified manner around the central shaft 132 to independently control the temperature at various regions of the substrate 108 as the process gas passes over, thereby facilitating the deposition of a material onto the upper surface of the substrate 108. While not discussed here in detail, the deposited material may include gallium arsenide, gallium nitride, or aluminum gallium nitride, among other materials.

Process gas supplied from a process gas supply source 172 is introduced into the process gas region 156 through a process gas inlet 174 formed in the flow module 136. The process gas inlet 174 is configured to direct the process gas in a generally radially inward direction over the substrate 108. During the film formation process, the substrate support 106 may be located in the processing position, which is adjacent to and at about the same elevation as the process gas inlet 174, allowing the process gas to flow up and round along flow path 173 across the upper surface of the substrate 108 in a laminar flow fashion. The process gas exits the process gas region 156 (along flow path 175) through a gas outlet 178 located on the side of the process chamber 100 opposite the process gas inlet 174. Removal of the process gas through the gas outlet 178 may be facilitated by a vacuum pump 180 coupled thereto.

The substrate support 106 while located in the processing position, divides the internal volume of the process chamber 100 into a process gas region 156 that is above the substrate 108, and a purge gas region 158 below the substrate support or susceptor 106. The substrate support 106 is rotated during processing by a central shaft 132 to minimize the effect of thermal and process gas flow spatial anomalies within the process chamber 100 and thus facilitate uniform processing of the substrate 108. The substrate support 106 is supported by the central shaft 132, which moves the substrate 108 in an up and down direction 134 during loading and unloading, and in some instances, during the processing of substrate 108.

The substrate support 106 may be formed from silicon carbide or graphite coated with silicon carbide to absorb radiant energy from the lamps 102 and conduct the radiant energy to the substrate 108. The substrate support or susceptor 106 may be a disk body, or may be a ring-shaped body that supports the substrate 108 from its edge to facilitate exposure of substrate 108 to the thermal radiation of the lamps 102.

The substrate 108 (not shown to scale) can be brought into the process chamber 100 and positioned onto the substrate support 106 through a loading port (not shown). The substrate support 106 is shown in an elevated processing position in process chamber 100, but may be vertically traversed by an actuator (not shown) to a loading position below the processing position to allow lift pins 105 to contact the lower plate 114, passing through holes in the substrate support 106 and the central shaft 132, and raise the substrate 108 from the substrate support 106. A robot (not shown) may then enter the process chamber 100 to engage and remove the substrate 108 therefrom through the loading port mentioned above. The substrate support 106 may be actuated afterwards up to the processing position to place the substrate 108, with its device side 116 facing up, on a top surface 110 of the substrate 106.

A circular shield 167 may be optionally disposed around the substrate support 106 and may be surrounded by a liner assembly 163. The shield 167 prevents or minimizes leakage of heat/light noise from the lamps 102 to the device side 116 of the substrate 108 while providing a pre-heat zone for the process gases. The shield 167 may be made from CVD silicon carbide, sintered graphite coated with silicon carbide, grown silicon carbide, opaque quartz, coated quartz, or any similar, suitable material that is resistant to chemical breakdown by process and purging gases.

The liner assembly 163 is sized to be nested within or surrounded by an inner circumference of the flow module 136. The liner assembly 163 shields the processing volume (i.e., the process gas region 156 and purge gas region 158) from metallic walls of the process chamber 100 since metallic walls may react with precursors and cause contamination in the processing volume. While the liner assembly 163 is shown as a single body, the liner assembly 163 may include one or more liners with different configurations.

As a result of backside heating of the substrate 108 from the substrate support 106, the use of a sensor such as an optical pyrometer 118 for temperature measurements/control on the substrate support 106 can be performed. This temperature measurement by the optical pyrometer 118 may also be done on substrate device side 116 having an unknown emissivity since heating the substrate top surface 110 in this manner is emissivity independent. As a result, the optical pyrometer 118 can only sense radiation from the hot substrate 108 that conducts from the substrate support or susceptor 106, with minimal background radiation from the lamps 102 directly reaching the optical pyrometer 118.

The present disclosure contemplates that other sensor devices (not shown) may be used and can monitor, for example, growth of layer(s) on the device side 116 of substrate 108. In addition to the external optical pyrometers and other external sensors, internal sensors can be used within the process chamber 100, in accordance with the present disclosure to measure the emissivity of the plurality of patterned regions and the emissivity of the non-patterned regions on the back of side 104 of substrate support 106. More specifically, internal pyrometers (not shown) within the process chamber 100, can be located within the purge gas region 158 and within the process gas region 156 to facilitate temperature determination on the back side 104 of the substrate support 106 as well as to collect temperature measurements to facilitate laser patterning, or to refine laser patterning, to enhance temperature and/or deposition uniformity.

As shown, a controller 190 is in communication with the processing chamber and it is used to control processes and methods, such as the operations described herein. The controller 190 is configured to receive data or input as sensors readings from sensor(s) such as the optical pyrometer 118. The controller unit 190 includes a central processing unit (CPU) 192 (e.g. a processor), a memory 194 containing instructions, and support circuits 196 for the CPU 192. The present disclosure contemplates that the process chamber 100 may include a camera, or monitoring device electrically coupled to the controller 190. The camera 200, for example, may be disposed in an opening 186 in the upper plate 128 between the upper plate 128 and the reflector 122. The CPU 192 may be one of any form of a general-purpose computer processor that can be used in an industrial setting. The support circuit 196 is conventionally coupled to the CPU 192 and may comprise cache, clock circuits, input/output subsystems, power supplies, and the like. Operational parameters such as power applied to heating lamps 102, a processing recipe, and operations are stored in the memory 194 as software routines. The software routines, when executed by the CPU 192, transform the CPU 192 into a specific-purpose computer (controller) 191. The software routines may also be stored and/or executed by a second controller (not shown) that is located remotely from the process chamber 100. The controller 190 and the processing chamber 100 are at least part of a system configured in the above manner to perform a process on a substrate.

While FIG. 1 illustrates one example of a processing chamber 100 that may benefit from aspects of the disclosure, it is contemplated that other chambers may also benefit. Thus, the disclosure is not limited to the specific chamber illustrated in FIG. 1.

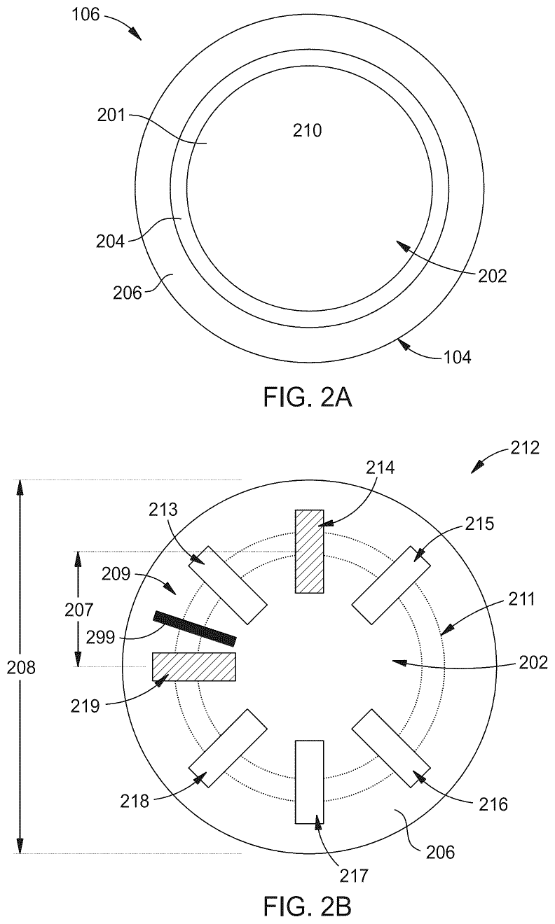

FIG. 2A shows an example of a susceptor 106 that may be used in the process chamber 100 of FIG. 1, according to embodiments of the present disclosure. The susceptor 106 includes a pocket 201 formed on top of a surface 202 of the substrate support or susceptor 106. The pocket 201 is defined by an annular-shaped edge 204 which is further bound by a rim 206. The pocket 201 includes a side wall (not shown) and a substrate receiving surface 210 for holding the substrate 108. For a given substrate 108, the substrate receiving surface 210 of the pocket 201 generally has a diameter only slightly larger than the substrate 108. When in use, the substrate 108 is centered in the pocket 201 on the substrate receiving surface 210 and a gap is maintained between the edge of the substrate 108 and the side wall (not shown) of the pocket 201. In some embodiments, the diameter 208 of the susceptor 106, including the rim 206, is from about 300 mm to about 500 mm while the inner radius of the pocket 201 is of about 100 mm to about 300 mm as shown in FIG. 2B.

As discussed above, methods and apparatus are provided herein for temperature tuning by emissivity variation on the back side 104 of the susceptor 106 by laser patterning. A plan view of the back side 104 of the susceptor 106, as that shown in FIG. 2B, provides an example of the back side 104 of the susceptor 106, shown in FIG. 2A that may be used in the process chamber 100 of FIG. 1, according to certain embodiments of the present disclosure. The susceptor 106 includes a plurality of patterned regions 213, 214, 215, 216, 217, 218, and 219 and a non-patterned region 209 with different emissivity values formed by laser patterning. The different emissivity values compensate for heat map or depositions non-uniformities during the manufacturing process or as dictated by a specific design functionality. The different emissivity values facilitate improved deposition uniformity by compensating for thermal variations which otherwise result in deposition non-uniformities.

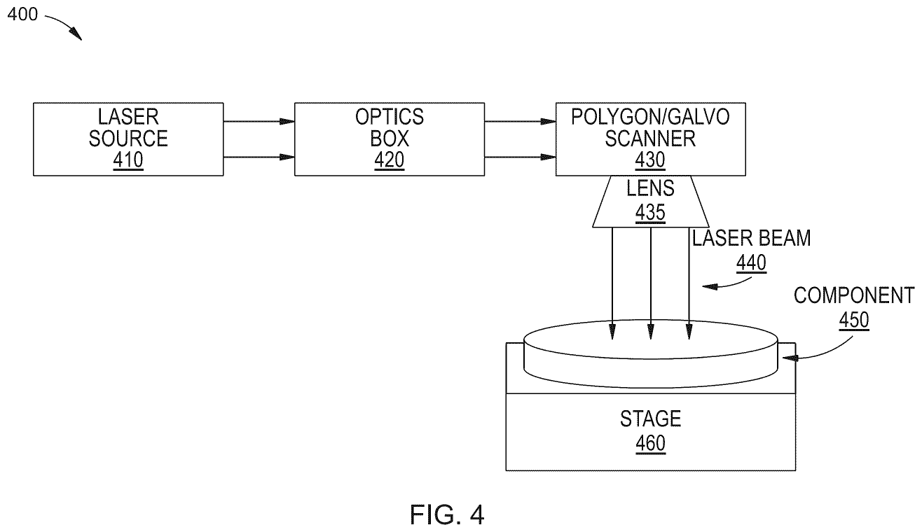

In one or more embodiments, the susceptor 106 in FIG. 2B includes a silicon carbide coating and a plurality of patterned regions 213, 214, 215, 216, 217, 218, and 219 and a non-patterned region 209 on the back side 104 of the susceptor 106. In one or more embodiments, the plurality of patterned regions 213, 214, 215, 216, 217, 218, and 219 form a spoked radial pattern 212 on the back side 104 of the susceptor 106. As shown in FIG. 2B, the plurality of patterned regions 213, 215, 216, 217, and 218 are represented as regions of lower emissivity (light regions) values while the plurality of patterned regions 214 and 219 are represented as regions of higher emissivity values (dark regions). The plurality of patterned regions 213, 214, 215, 216, 217, 218, and 219 forming the spoked radial pattern 212 are obtained by laser patterning, as will be explained further in FIG. 4, on the back side 104 of the substrate support. While a spoked radial pattern is illustrated, other patterns are also contemplated, and may be dictated by empirically-derived or modeled heat maps, deposition profiles, or other factors.

In one or more embodiments, the plurality of patterned regions 213, 214, 215, 216, 217, 218, and 219 forming the spoked radial pattern 212 on the back side 104 of the susceptor 106 have depths ranging from about 5 microns to about 10 microns, providing a lower depth of lasering unlike, for example, drilling hex holes which is characterized by depths of about 50 microns to 100 microns. Therefore, the methods and apparatus provided herein can be implemented on conventional substrate supports, without the need for any modifications. The laser patterning processes disclosed herein result in reduced time and cost for machining. In one or more embodiments, the plurality of patterned regions 213, 214, 215, 216, 217, 218, and 219 forming the spoked radial pattern 212, have rectangular dimensions ranging from about 20 mm to about 40 mm by about 60 mm to about 90 mm, but these dimensions are merely illustrative, and other dimensions are also contemplated. Moreover, aspects of the present disclosure allow for emissivity adjustment of coated substrate supports. For example, coated substrate supports typically have coatings of relatively thin depth, which is easily breached (e.g., completely traversed) by drilling. In contrast, laser patterning as described herein affects the coating to a relatively small depth, such that the coating is not completely patterned through the thickness thereof when using laser patterning.

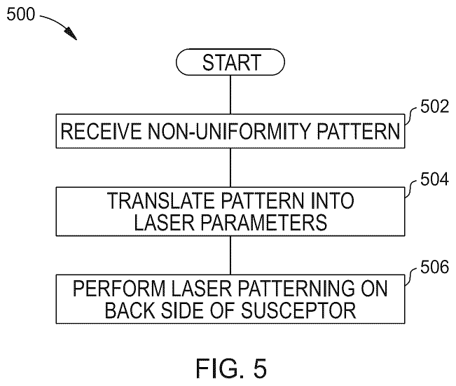

In one or more embodiments, one or more internal pyrometers can be used within the process chamber 100 of FIG. 1, in accordance with the disclosure to measure the emissivity of the plurality of patterned regions 213, 214, 215, 216, 217, 218, and 219 and the emissivity of the non-patterned region 209 on the back side 104 of susceptor 106 after the laser patterning method 500 shown in FIG. 5 is performed on the back side 104 of the susceptor 106 using specific lasering parameters discussed in the description of FIG. 4.

In one or more embodiments, an internal pyrometer measuring a region 211 shown in FIG. 2B of the back side 104 of the susceptor 106 can be located within the purge gas region 158 and/or within the process gas region 156 of the process chamber 100 shown in FIG. 1. The internal pyrometer is configured to measure the emissivity of the plurality of patterned regions 213, 214, 215, 216, 217, 218, and 219 and the emissivity of the non-patterned region 209 on the back side 104 of the substrate support 106 in the process chamber 100 of FIG. 1. A reference signature 299 shown as a fully filled rectangular region of smaller rectangular dimensions on the back side 104 of the substrate support 106, of known emissivity is used to calibrate the internal pyrometer during processing or otherwise needed as a reference mark. While not discussed here in detail, the pyrometer reading location 211 is measured at a radius or diameter that traverses the spoked radial pattern 212 and can vary within the back side 104 of the substrate 106. In one of more embodiments, the spot size of the pyrometer reading location 211 can have dimensions ranging from about 10 mm to 15 mm, but other dimensions are contemplated. In one example, the reference signature has a smaller area or width compared to other regions so as reduced effect on temperature modulation of the substrate support 106.

In one or more embodiments, the light regions (e.g., 213, 215, 216, 217, and 218) forming the spoked radial pattern 212 are configured via the tuning of lasering parameters (as will be further discussed in the description of FIG. 4) to have a plurality of first emissivity values while the dark regions (e.g., 214 and 219) forming the spoked radial pattern 212 are configured to have (as will be discussed later in FIG. 4) a plurality of second emissivity values.

In one or more embodiments, the plurality of the first emissivity values is smaller than the plurality of the second emissivity values while the plurality of the first emissivity values is lower than the emissivity value of the non-patterned region 209. In one or more embodiments, the plurality of the first emissivity values and the plurality of the second emissivity values are of at least 0.7. By selectively adjusting lasering parameters, as we will further explain in FIG. 4, during laser patterning on the back side 104 of the susceptor 106, temperature adjustment by emissivity variation is achieved across the susceptor 106. Temperature adjustment by emissivity variation on the back side 104 of the susceptor 106 leads to regions of lower and higher temperature absorption, providing in this way a method to compensate for heat map or depositions non-uniformities.

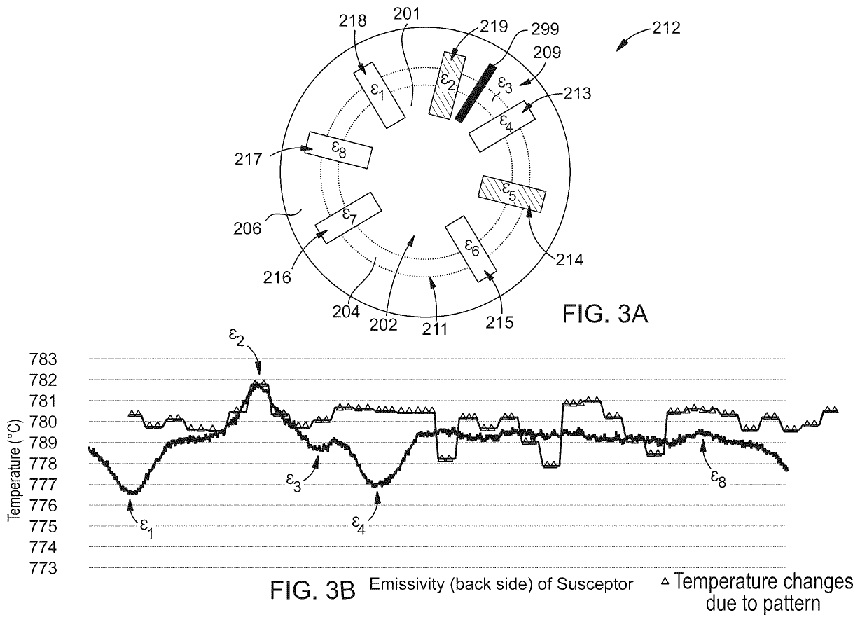

FIG. 3A shows a plurality of first emissivity values and a plurality of second emissivity values of the plurality of patterned regions 213, 214, 215, 216, 217, 218, 219 and an emissivity value of the non-patterned region 209 on the back side 104 of susceptor 106 that comprises the spoked radial pattern 212 discussed in FIG. 2B. The plurality of first emissivity values and the plurality of second emissivity values obtained based on lasering parameters will be further discussed in FIG. 4.

In one or more embodiments, the spoked radial pattern 212 shown in FIG. 3A on the back side 104 of susceptor 106 includes light region 218 of emissivity ε₁, dark region 219 of emissivity ε₂, non-patterned region 209 of emissivity ε₃, light region 213 of emissivity ε₄, dark region 214 of emissivity ε₅, light region 215 of emissivity ε₆, light region 216 of emissivity ε₇ and light region 217 of emissivity ε₈.

FIG. 3B shows a schematic plot of temperature in degree Celsius as a function of the emissivity values for the plurality of patterned regions shown in FIG. 3A, as measured on the back side 104 of the susceptor 106 with an internal pyrometer according to embodiments of the present disclosure. Illustrative emissivity values have been labeled in the schematic plot of FIG. 3B and correspond to emissivity value ε₁ for the light region 218, emissivity value ε₂ for the dark region 219, emissivity value ε₃ corresponding to the non-patterned region 209, emissivity value ε₄ for the light region 213, and emissivity value ε₈ for the light region 217.

Superimposed on the schematic plot of temperature in degree Celsius as a function of the emissivity values from FIG. 3A, FIG. 3B displays the temperature changes in degree Celsius measured across the back side 104 of the susceptor 106. In one or more embodiments, the superimposed plot of temperature shows a temperature modulation of about +3 degree Celsius to about −2.5 degree Celsius measured at a temperature of 780 degree Celsius in the process chamber of FIG. 1 after performing laser patterning on the back side 104 of silicon carbide coated susceptor 106. This variation in temperature as a result of laser patterning, which will be further discussed in FIG. 4, has the effect of increasing or decreasing emissivity of the back side 104 of the susceptor 106 based on specific lasering parameters (e.g., increased or decreased emissivity) chosen. Using method 500 (shown in FIG. 5) the thickness non-uniformity map can be transferred on to the back side of a susceptor and thus compensate in this way for heat map or depositions non-uniformities.

FIG. 4 shows the schematics of a laser patterning system 400, according to embodiments of the present disclosure. The laser source 410 includes a continuous wave (CW) laser (e.g., a CW CO₂ laser or a CW green laser) and generates a coherent beam of light that is directed into an optics box 420. In one or more embodiments, the optics box 420 shapes and focuses the beam of light using an array of mirrors and lenses to control the beam's focus and path. The laser beam is then directed into a scanner 430, that steers the beam across the target surface. The scanner 430 works in conjunction with a lens 435 (e.g., an F-theta lens) to maintain focus and ensure a consistent spot size across the entire scanning field. In one or more embodiments, the laser patterning system 400 is characterized by a focal length ranging from about 70 mm to about 255 mm.

A high frequency ultrashort pulsed laser (e.g., a femtosecond laser) can be used. Laser patterning may be performed by moving the laser beam 440 (e.g., rastering) in a pattern or by moving the component 450 (e.g., the susceptor 106) disposed on the stage 460 that is configured to move in an x, y, and/or z direction.

Rastering (e.g., a back-and-forth pattern) of the laser beam 440 can be achieved through galvanometers (galvo) systems and/or movable wedge systems within the scanner 430. Galvo systems generally utilize fast-moving mirrors to direct a laser beam in a desired pattern (e.g., a back-and-forth pattern). Movable wedge systems can involve the physical movement of either the laser head or the target itself through linear actuators or motors to create the raster pattern.

In laser material processing, hatch distance can refer to the spacing between adjacent raster lines that determines the application density of a laser on a material. The spacing between raster lines directly affects, among other parameters, the engraving depth, surface smoothness and energy input. Generally, a smaller hatch distance can result in greater overlap of laser paths for a more uniform treatment, whereas larger hatch distance allows for quicker processing with less intensity. In one or more embodiments, hatch type can describe the pattern or direction of the raster lines. For example, single-directional (e.g., horizontal), where the laser moves back and forth in one direction, or cross-hatch patterns that apply laser paths in two perpendicular directions for a more even coverage can be implemented during the laser patterning process either alone or in combination. By selectively adjusting laser patterning processing parameters while following a rastering pattern, for example, kinking features can be reduced, thus leading to a smoothening and/or softening of a surface by removing peaks and sharp edges. Additionally or alternatively, rastering patterns can be made to overlap (i.e. reduced spacing or no spacing between the raster lines) to further enhance the softening effect on the surface and the engraving depth or the laser can be adjusted (e.g., momentarily turned off) so that an intersection is not processed more than once, depending on the desired functionality to be achieved.

In one or more embodiments of the present disclosure, a high-powered ultraviolet (UV) laser with a nanosecond pulse width and a spot size between about 20 μm to about 40 μm such as of between about 25 μm to about 38 μm was used in the laser patterning process with a characteristic output power of 3 Watts (peak) and 2.5 Watts during the laser patterning process.

In one or more embodiments, laser patterning processing parameters used on the surface component 450, such as the back side 104 of a susceptor 106 shown in FIG. 2A, were characterized by a frequency ranging from about 20 MHz to about 100 MHz such as from about 30 MHz to about 90 MHz. Both horizontal hatch patterns and cross-hatch patterns with a full overlap and hatch spacing from about 60 μm to about 100 μm such as 90 μm were used in the present disclosure to obtain the resulting spoked radial pattern 212 shown in FIG. 2B and FIG. 3A.

In one or more embodiments, the spoked radial pattern 212 includes light regions and dark regions, as shown in FIG. 3B, characterized by a plurality of first emissivity values and a plurality of second emissivity values, respectively. The light regions and dark regions are obtained by selectively adjusting the laser patterning speed in frequency space, which are dependent on pulse power and pulse width. Laser patterning speeds can range, for example, from about 10 mm/sec to about 2000 mm/sec such as from about 30 mm/sec to about 1000 mm/sec. For example, referring to FIG. 2B, FIG. 3A and FIG. 3B, a lower emissivity value of ε₁=0.805 was achieved in the light region 218 where, for example, one laser patterning speed tested was from about 20×0.03×800 mm/sec to about 60×0.06×900 mm/sec. In contrast, a higher emissivity value of ε₂=0.906 was achieved in the dark region 219 where, for example, the laser patterning speed used was significantly lower than in the 218 light region, from about 20×0.03×30 mm/sec to about 60×0.06×60 mm/sec.

As discussed above, slower laser patterning speeds used with controlled hatch spacing are generally found to increase the emissivity of the surface, such as on the back side 104 of the susceptor 106, thus creating high temperature absorption regions. Alternatively or additionally, by selective decreasing the power output of the laser source, faster laser patterning speeds can be achieved through a softening of the surface by removing peaks and sharp edges leading to regions of lower emissivity, creating in this way lower temperature absorption regions. The lasering parameters, as discussed above and described herein comprising the laser patterning on the back side 104 of the susceptor 106 shown, for example, in FIG. 2A, characterized by the spoked radial pattern 212 shown in FIG. 2B and FIG. 3A are not intended to limit the scope of the disclosure provided herein since other lasering parameters either alone or in combination to those recited above can lead to similar results and thus achieve the intended outcome of this disclosure, that is, that of temperature tunning by emissivity variation on susceptor by laser patterning.

Not to be bound by theory, but it is believed that the laser patterning changes properties of the target material, resulting in changes in emissivity where laser patterning occurs. For example, one or more of surface roughness or smoothness, texture, crystallography, reflectivity, or other properties, may be changed to result in a corresponding emissivity change. Variations in laser power, wavelength, treatment time, or other properties, account for resulting differences in emissivity in treated locations.

In one or more embodiments, laser patterning on the back side 104 of a silicon carbide coated susceptor 106 results in the temperature modulation or variation shown in FIG. 3B. The temperature changes/modulations due to the emissivity variation (shown in FIG. 3B) resulting from the plurality of the patterned regions shown in FIG. 2B, are achieved from adjustments of lasering parameters described above. Using this method, the thickness non-uniformity map can be transferred onto the back side 104 of the silicon carbide coated susceptor 106 as shown in FIG. 2B in order to compensate for heat map or depositions non-uniformity. It is also contemplated in this disclosure that the laser pattering method, further discussed below in FIG. 5, can also be used on specific portions of the susceptor, such as under the arms or around the points of contact holding the susceptor to compensate for temperature loss.

FIG. 5 is a schematic flow diagram view of the method 500 of laser patterning on the back side 104 of susceptor 106.

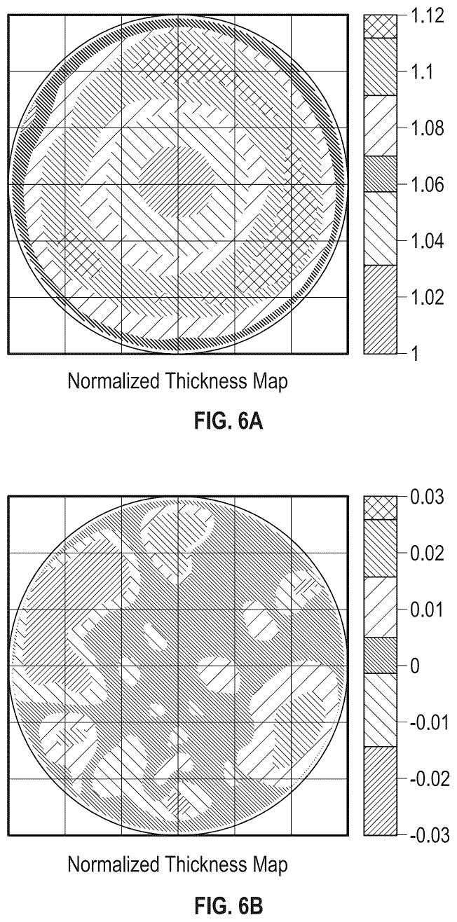

Operation 502 includes receiving the non-uniformity pattern generated by heat map or deposition non-uniformity. In one or more embodiments, the non-uniformity pattern may be a heat map of a substrate during processing, which may be captured during one or more points in time of processing. Additionally or alternatively, the non-uniformity pattern could be a thickness uniformity map, or a topography map, of a deposited film that is formed within the processing chamber. In some instances, the non-uniformity pattern can be chamber specific and/or design specific. In other words, the non-uniformity pattern is a pattern across the substrate, or the surface of the substrate, exhibiting non-uniformity. For example, FIGS. 6A and 6B illustrate non-uniform film thickness maps across the surface of substrates. As illustrated, the film thickness maps are non-uniform in that some areas of substrate surface vary in film thickness relative to other areas of the substrate surface. These thickness differences across the substrate surface result in non-uniform film formation on the substrates. While FIGS. 6A and 6B illustrate non-uniform thickness maps, it is also contemplated in this disclosure that a non-uniform heat map would appear similar to the non-uniform thickness map. That is, the heat map is non-uniform in that some areas of substrate surface vary in temperature relative to other areas of the substrate surface. These temperature differences result in non-uniform film formation on the substrate.

The present disclosure further contemplates that while some examples of non-uniformity patterns are mentioned above, a non-uniformity pattern could additionally or alternatively include (or be converted to) a digital file created in the controller unit 190 shown in FIG. 1, or another computer. Additionally or alternatively, the digital file created in the controller unit 190, for example, can be dictated by a specific design functionality and or deposition morphology to intentionally create areas of low temperature and high temperature on or within the substrate, thus creating a temperature modulation across the substrate that does not necessarily results in a more uniform temperature of a substrate support In such circumstances, it is envisioned that the non-uniformity pattern may account for other factors (beyond susceptor temperature uniformity) which result in more uniform deposition, by adjusting the substrate support temperature profile to account for such factors. Thus, it is contemplated that use of deposition uniformity inputs comprising the non-uniformity pattern can compensate—indirectly—for difficult-to-determine influences on deposition profiles.

The non-uniformity pattern of operation 502 is translated into lasering parameters in operation 504 by selectively adjusting lasering parameters, such as laser frequency, hatch distance, hatch pattern, and lasering speeds and creating a map of an emissivity profile (depicted in FIG. 2B) in frequency space to target specific regions of the backside 104 of the susceptor 106. For example, if a non-uniformity pattern indicates areas of relatively lower deposition thickness, or relatively lower temperature, on a substrate, than the emissivity profile of a susceptor is selected to compensate for these relatively lower deposition thicknesses and/or temperatures. In such an example, the emissivity profile of the susceptor includes areas of increased emissivity (e.g., values closer to 1) that corresponded to supported areas of the substrate of relatively lower deposition thickness or temperature. Correspondingly, the emissivity profile of the susceptor includes areas of reduced emissivity (e.g., values closer to 0) that corresponded to supported areas of the substrate of relatively higher deposition thickness or temperature. In this manner, the emissivity of the susceptor is changed to affect temperature and or deposition of on the substrate corresponding to the mapped emissivity profile, which is determined according to the non-uniformity pattern previously discussed.

In one or more embodiments, the emissivity profile is translated into laser parameters by using a high frequency UV ultrashort pulsed laser with a nanosecond pulsed width and spot size between about 20, yielding laser speeds in the range from about 10 mm/sec to about 2000 mm/sec, such as from about 30 mm/sec to about 900 mm/sec. In one or more embodiments of the resent disclosure, a map of an emissivity profile is created in frequency space by using a frequency from about 20 μm to about 40 μm such as of between about 25 μm to about 38 μm with a characteristic output power of 3 Watts (peak) and 2.5 Watts during operation 504 of method 500. Horizontal hatch patterns and cross-hatch patterns with a full overlap and hatch spacing from about 60 μm to about 100 μm such as 90 μm and frequencies raging from about 20 MHz to about 100 MHz, such as from about 30 MHz to about 90 MHz were used in the present disclosure to generate the map of an emissivity profile in frequency space.

Using the parameters mentioned herein, a map of an emissivity profile is constructed in frequency space. The map comprises of regions characterized by higher emissivity values that correspond to slower lasering speeds, controlled hatch spacing and overlap and of regions characterized by low emissivity values wherein the speeds used are faster lasering speeds achieved by decreasing the power and thus leading to a softening of the surfaces by removing peaks and sharp edges.

Once the map of the emissivity profile is completed (i.e., areas of light regions and areas of dark regions have been determined and lasering parameters described above have been set according to the non-uniformity pattern from block 502) operation 506 of method 500 is performed.

Operation 506 includes performing laser patterning on back side 104 of silicon carbide coated susceptor 106 in order to achieve a desired emissivity pattern, such as the radial spoked pattern 212 shown in FIG. 2B and FIG. 3A. In one or more embodiments, an analog laser map (e.g., a sketched illustration such as that shown in FIG. 2A) containing the emissivity profile in frequency space can be uploaded to controller 190 and therein after transferred to the back side 104 of the silicon carbide coated susceptor 106 by using the laser pattering system shown in FIG. 4.

The present disclosure further contemplates that while aspects of the disclosure refer to applying lasered emissivity patterns to a substrate support, similar processes may be performed on other process chamber components. Other process chamber components include, without limitation, to preheat rings, support shafts, lift pins, liners, reflectors, clamp rings, chamber bodies or lids, injectors, windows or domes, lamp heads, and the like.

The present disclosure relates to temperature tuning by emissivity variation on susceptor by laser patterning. Specifically, patterned regions of reduced emissivity achieved by laser patterning and characterized by lower temperature absorption can be used under the substrate area to compensate based on the map of thickness and can correct static inherent non-uniformities caused by lift pins, arm shadowing and edge roll off. The method and system described herein can be used on current silicon carbide coated susceptors as the lasering depth is significantly low, about less than 10 microns. The apparatus and method described in the present disclosure can produce an analog substrate map specific to a particular chamber and/or specific to a desired morphology. Furthermore, the methods described herein can be achieved using current lasering techniques on current susceptors in reduced time and thus with minimal cost for machining.

While the foregoing is directed to embodiments of the present disclosure, other and further embodiments of the disclosure may be devised without departing from the basic scope thereof, and the scope thereof is determined by the claims that follow.

What is claimed is:

1. A chamber component of a processing chamber, comprising:
a body; and
a surface on one side of the body, the surface comprising a plurality of patterned regions and a non-patterned region, and the plurality of patterned regions having a different emissivity than the non-patterned region.

2. The chamber component of claim 1, wherein the chamber component comprises a susceptor.

3. The chamber component of claim 1, further comprising:
a silicon carbide coating on the one side of the body, wherein the silicon carbide coating comprises the plurality of patterned regions.

4. The chamber component of claim 1, wherein the plurality of patterned regions comprises a depth ranging from about 5 microns to about 40 microns.

5. The chamber component of claim 1, wherein the plurality of patterned regions comprises a spoked radial pattern.

6. The chamber component of claim 5, wherein the spoked radial pattern comprises light regions and dark regions, the light regions having a plurality of first emissivity values and the dark regions having a plurality of second emissivity values, wherein the plurality of the first emissivity values is smaller than the plurality of the second emissivity values and the first emissivity values are lower than the non-patterned region.

7. The chamber component of claim 6, wherein the light regions and the dark regions have dimensions ranging from about 20 mm to about 40 mm by about 60 mm to about 90 mm.

8. The chamber component of claim 6, wherein the plurality of the first emissivity values and the plurality of the second emissivity values are of at least 0.7.

9. A method comprising:
receiving a chamber component of a processing chamber; and
performing laser patterning on one side of a body of the chamber component of the processing chamber to form a plurality of patterned regions and a non-patterned region, and the plurality of patterned regions having a different emissivity than the non-patterned region.

10. The method of claim 9, wherein the chamber component comprises a susceptor.

11. The method of claim 9, further comprising:
a silicon carbide coating on the one side of the body, wherein the silicon carbide coating comprises the plurality of patterned regions.

12. The method of claim 9, wherein the plurality of patterned regions comprises a depth ranging from about 5 microns to about 40 microns.

13. The method of claim 9, wherein the plurality of patterned regions comprises a spoked radial pattern.

14. The method of claim 13, wherein the spoked radial pattern comprises light regions and dark regions, the light regions having a plurality of first emissivity values and the dark regions having a plurality of second emissivity values, wherein the plurality of the first emissivity values is smaller than the plurality of the second emissivity values and the first emissivity values are lower than the non-patterned region.

15. The method of claim 14, wherein the light regions and the dark regions have dimensions ranging from about 20 mm to about 40 mm by about 60 mm to about 90 mm.

16. The method of claim 14, wherein the plurality of the first emissivity values and the plurality of the second emissivity values are of at least 0.7.

17. A processing system configured to perform a process on a substrate comprising:
a chamber body;
a plurality of lamps; and
a silicon carbide coated susceptor disposed inside the chamber body further comprising:
the silicon carbide coated susceptor having a surface comprising a plurality of patterned regions and a non-patterned region;
the plurality of patterned regions having a different emissivity than the non-patterned region; and
the plurality of patterned regions comprising a spoked radial pattern.

18. The processing system of claim 17, wherein the spoked radial pattern comprises light regions and dark regions, the light regions having a plurality of first emissivity values and the dark regions having a plurality of second emissivity values, wherein the plurality of the first emissivity values is smaller than the plurality of the second emissivity values and the first emissivity values are lower than the non-patterned region.

19. The processing system of claim 18, wherein the light regions and the dark regions have dimensions ranging from about 20 mm to about 40 mm by about 60 mm to about 90 mm.

20. The processing system of claim 18, wherein the plurality of the first emissivity values and the plurality of the second emissivity values are of at least 0.7.
